(19) United States
(12) Patent Application Publication
(10) Pub. No.: US 2026/0308762 A1
(43) Pub. Date: Oct. 8, 2026

(54) PROCESS FOR PREPARING OF TRANSITION METAL-CONTAINING FILMS

(71) Applicant: BASF SE, Ludwigshafen am Rhein (DE)

(72) Inventors: Alexander Georg HUFNAGEL, Ludwigshafen am Rhein (DE); Sinja Verena KLENK, Ludwigshafen am Rhein (DE); Hagen WILMER, Ludwigshafen am Rhein (DE); Daniel LOEFFLER, Ludwigshafen am Rhein (DE)

(21) Appl. No.: 18/880,585

(22) PCT Filed: Jul. 3, 2023
(86) PCT No.: PCT/EP2023/068183

§ 371 Date: Jan. 2, 2025

(30) Foreign Application Priority Data
Jul. 6, 2022 (EP) 22183453.4

(51) Int. Cl. C23C 16/455

(52) U.S. Cl. CPC C23C 16/45553; C23C 16/45527

(57) ABSTRACT

The present invention is in the field of processes for preparing of transition metal-containing films on substrates, in particular atomic layer deposition processes. It relates to a process for preparing a transition metal-containing film on a substrate comprising (a) forming an organic-inorganic hybrid film by repeatedly bringing the substrate in contact with a transition metal-containing compound and an organic acid in the gaseous state, wherein the organic acid is oxalic acid, glyoxylic acid, or glycolic acid, and (b) decomposing the organic-inorganic hybrid film into a transition metal-containing film by thermal treatment.

The present invention is in the field of processes for preparing of transition metal-containing films on substrates, in particular atomic layer deposition processes.

With the ongoing miniaturization, e.g. in the semiconductor industry, the need for thin transition metal-containing films on substrates increases while the requirements on the quality of such films become stricter. Thin transition metal-containing films serve different purposes such as barrier layers, conducting features, or capping layers. Several methods for the generation of transition metal films are known. One of them is the deposition of film forming compounds from the gaseous state on a substrate. In order to bring transition metal atoms into the gaseous state at moderate temperatures, it is necessary to provide volatile precursors, e.g. by complexation of the metals or semimetals with suitable ligands. These precursors need to be sufficiently stable for evaporation, but on the other hand they need to be reactive enough to react with the surface of deposition. For obtaining films of elemental transition metal it is necessary to reduce the deposited precursors. Typically, a reducing agent is used either during deposition or after deposition.

US 2019/0 249 300 A1 discloses a method for depositing a transition metal-containing film, wherein formic acid is used as co-reagent which is likely not integrated into the film at any time. However, it has turned out to be difficult to obtain very thin homogeneous films of elemental transition metals using this process.

WO 2004/035 858 A2 discloses a method for depositing of a metal film of Pd, Rh, Ru, Pt and Ir by using a reducing gas such as hydrogen, glyoxylic acid or oxalic acid. The transition metals are reduced after each deposition step. Once again, it is difficult to obtain very thin homogeneous films of elemental transition metals using this process.

US 2021/398 848 A1 discloses a process for selective deposition of metals employing formic acid. However, low film growth rates are generally observed.

It was hence an object of the present invention to provide a process in which very thin homogeneous transition metal-containing films are available, in particular transition metal films. It was aimed at a process yielding high film growth rates. This process was aimed to be broadly applicable to different transition metals and different substrates. The process should leave as little by-products in the film as possible yielding films with a low contamination level with undesirable residues.

These objects were achieved by a process for preparing a transition metal-containing film on a substrate comprising
(a) forming an organic-inorganic hybrid film by repeatedly bringing the substrate in contact with a transition metal-containing compound and an organic acid in the gaseous state, wherein the organic acid is formic acid, oxalic acid, glyoxylic acid, or glycolic acid, and
(b) decomposing the organic-inorganic hybrid film into a transition metal-containing film by thermal treatment.

According to the present invention a transition metal-containing film is prepared. Transition metals contain the elements Sc, Ti, V, Cr, Mn, Fe, Co, Ni, Cu, Zn, Y, Zr, Nb, Mo, Ru, Rh, Pd, Ag, Cd, La, Hf, Ta, W, Re, Os, Ir, Pt, Au, Hg. Preferred transition metals are Cr, Mn, Fe, Co, Ni, Cu, Nb, Mo, Ru, Rh, Pd, Ag, W, Re, Os, Ir, Pt, Au, more preferably Co, Ni, Cu, Nb, Mo, W, in particular Ni or Ru. The transition metal-containing film may contain one transition metal or it may contain more than one transition metal, for example two or three. Transition metal-containing in the context of the present invention means that the film contains more than traces of transition metal, usually at least 1 wt.-% such as at least 10 wt.-% or at least 30 wt.-%. The transition metal-containing film can be an inorganic film such as a film of metal, a metal nitride, a metal carbide, a metal carbonitride, a metal alloy, an intermetallic compound or mixtures thereof. Preferably, the transition metal-containing film is a transition metal film, i.e. a film which contains elemental transition metals. A transition metal film usually contains at least 90 wt.-% transition metal or at least 95 wt.-% or at least 99 wt.-%. A transition metal film typically exhibits high electrical conductivity, usually at least 10⁴ S/m, preferably at least 10⁵ S/m, in particular at least 10⁶ S/m.

The transition metal-containing film is on a substrate. The substrate can be of any solid material. These include for example metals, semimetals, oxides, nitrides, and polymers. The substrate may be of one homogeneous material or it may be of a mixture of different materials. Examples for metals are aluminum, steel, zinc, and copper. Examples for semimetals are silicon, germanium, and gallium arsenide. Examples for oxides are silicon dioxide, titanium dioxide, and zinc oxide. Examples for nitrides are silicon nitride, aluminum nitride, titanium nitride, and gallium nitride. Examples for polymers are polyethylene terephthalate (PET), polyethylene naph-thalene-dicarboxylic acid (PEN), and polyamides.

The substrate can have any shape. These include sheet plates, films, fibers, particles of various sizes, and substrates with trenches or other indentations. The substrate can be of any size. If the substrate has a particle shape, the size of particles can range from below 100 nm to several centimeters, preferably from 1 μm to 1 mm. In order to avoid particles or fibers to stick to each other due to the film preparation process, the particle or fiber substrate is preferably kept in motion during the film preparation process. This can, for example, be achieved by stirring, by rotating drums, or by fluidized bed techniques.

In step (a) of the process of the present invention an organic-inorganic hybrid film is formed by repeatedly bringing the substrate in contact with a transition metal-containing compound and an organic acid in the gaseous state. This means that a sequence containing bringing the substrate in contact with a transition metal-containing compound and an organic acid in the gaseous state is sequentially performed at least two times or at least five times or at least ten times or at least 50 times. Generally, the sequence is performed not more than 1000 times. As an example, for preparing thin films the sequence is performed two to ten times or five to 50 times. The sequence may reflect one cycle of an atomic layer deposition process, i.e. the sequence contains bringing the substrate in contact with a transition metal-containing compound for a certain time, removing any residual transition metal-containing compound from the gas phase, for example by purging with an inert gas or by evacuation, followed by bringing the substrate in contact with an organic acid for a certain time and removing any residual organic acid from the gas phase, for example by purging with an inert gas or by evacuation. Purging can take 0.5 s to 1 min, preferably 5 to 30 s, more preferably from 10 to 25 s, in particular 15 to 20 s.

In this way, an organic-inorganic hybrid film is formed on the substrate, namely if the surface of the substrate reacts with the transition metal-containing compound to form a thin layer which subsequently reacts with the organic acid. Hence, the organic-inorganic hybrid film contains a transition metal and an organic acid or its salt. At least part of the organic acid or its salt may be bound or coordinated to the transition metal. Diprotic organic acid molecules can be bound or coordinated to one transition metal atom or to two transition metal atoms. The latter may form polymeric structures throughout the organic-inorganic hybrid film.

A variety of transition metal-containing compounds can be used. Generally, any transition metal-containing compound, which can be brought into the gaseous state, is suitable. These compounds include transition metal alkyls such as dimethyl zinc; transition metal alkoxylates such as tri-iso-propoxy iron; transition metal carbenes such as tris(neopentyl)neopentylidene tantalum or bisimidazolidinyliden ruthenium chloride; transition metal halides such as tantalum pentachloride, molybdenum pentachloride, tungsten hexachloride; carbon monoxide complexes like hexacarbonyl chromium or tetracarbonyl nickel.

Further suitable transition metal-containing compounds are transition metal complexes in which a ligand coordinates to the transition metal via an oxygen and or a nitrogen atom. These complexes may contain a ligand which coordinates via at least one nitrogen atom to the transition metal atom or at least one oxygen atom which coordinates to the transition metal atom or at least one nitrogen atom and at least one oxygen atom which coordinate to the transition metal atom or at least two nitrogen atoms which coordinate to the transition metal atom or at least two oxygen atoms which coordinate to the transition metal atom. These complexes can contain an ethylene diamine derivative ligand such as N,N,N′N′-tetramethylethylenediamine, for example bis(N,N,N′N′-tetramethylethylenediamine) niobium chloride; an ethanolamine derivative ligand such as dimethylamino-2-propoxide or dimethylamino-t-butoxide, for example bis(dimethyla-mino-2-propanolato) nickel (Ni(dmap)₂); an imino ligand, for example bis(tert-butylimino)bis(di-methylamido)molybdenum or bis(tert-butylimino)bis(dimethylamido)tungsten; a diketonate ligand, for example bis(2,2,6,6-tetramethyl-3,5-heptanedionato) manganese; an acetylacetonate ligand, for example bis(acetylacetonato)nickel; an acetamidinat ligand, for example bis(N,N′-diisopropylacetamidinato)nickel (Ni(iPrAMD)₂); diketimine ligands such as penta-2,4-diimine derivates, for example bis(N,N′-diethylpenta-2,4-diimino)cobalt. It is also possible that the transition metal containing compound contains different ligands, such as two or three different ligands which coordinates to the transition metal via an oxygen and or a nitrogen atom, for example bis(acetylacetonato)-N,N,N′N′-tetramethylethylenediamine-nickel (Ni(acac)₂(tmeda)).

Preferably, the transition metal-containing compound is a transition metal cyclopentadienyl complex. These can contain one or two cyclopentadienyl ligands, preferably two. These can be the same or different to each other. The transition metal cyclopentadienyl complex may only contain cyclopentadienyl ligands or it may contain one or two cyclopentadienyl ligands and at least one other ligand. The cyclopentadienyl ligands can be unsubstituted cyclopentadienyl, i.e. C₅H₅, or substituted cyclopentadienyl in which at least one hydrogen is substituted, for example with an alkyl group such as methyl, ethyl, n-propyl or iso-propyl like in ethyl-cyclopentadienyl. Examples for transition metal cyclopentadienyl complexes are dicyclopentadienyl nickel, di(ethylcycopen-tadienyl) manganese or di(pentamethylcyclopentadienyl) ruthenium.

The transition metal-containing compound preferably has a molecular weight of up to 1000 g/mol, more preferrably up to 800 g/mol, in particular up to 600 g/mol, such as up to 500 g/mol.

Preferably, the transition metal-containing compound has a melting point ranging from −80 to 125 °C, preferably from −60 to 80 °C, even more preferably from −40 to 50 °C, in particular from −20 to 20 °C. It is advantageous if the transition metal-containing compound melts to give a clear liquid which remains unchanged until a decomposition temperature.

Preferably, the transition metal-containing compound has a decomposition temperature of at least 80 °C, more preferably at least 100 °C, in particular at least 120 °C, such as at least 150 °C. Often, the decomposition temperature is not more than 250 °C. The transition metal-containing compound has a high vapor pressure. Preferably, the vapor pressure is at least 1 mbar at a temperature of 200 °C, more preferably at 150 °C, in particular at 120 °C. Usually, the temperature at which the vapor pressure is 1 mbar is at least 50 °C.

The organic acid is formic acid, oxalic acid, glyoxylic acid, or glycolic acid. It can be one organic acid or more than one organic acid, for example two or three. If more than one organic acid is chosen, it can be used as mixture or it can be used in different cycles, for example one organic acid is chosen in one cycle and another acid is chosen in the next cycle. Preferably, the organic acid is formic acid or oxalic acid, in particular oxalic acid.

The transition metal-containing compound or the organic acid used in the process according to the present invention are used at high purity to achieve the best results. High purity means that the substance used contains at least 90 wt.-% transition metal-containing compound or organic acid, preferably at least 95 wt.-%, more preferably at least 98 wt.-%, in particular at least 99 wt. %. The purity can be determined by elemental analysis according to DIN 51721 (Prüfung fester Brennstoffe-Bestimmung des Gehaltes an Kohlenstoff und Wasserstoff-Verfahren nach Rad-macher-Hoverath, August 2001).

The transition metal-containing compound or the organic acid is brought in contact with the solid substrate from the gaseous state. It can be brought into the gaseous state for example by heating it to elevated temperatures. In any case a temperature below the decomposition temperature of the transition metal-containing compound or the organic acid has to be chosen. The decomposition temperature is the temperature at which the pristine transition metal-containing compound or the organic acid begins changing its chemical structure and composition. Preferably, the heating temperature ranges from 80 °C to 300 °C, more preferably from 100 °C to 290 °C, even more preferably from 160 °C to 280 °C, in particular from 180 °C to 260 °C.

Another way of bringing the compound of general formula (I) or (II) into the gaseous state is direct liquid injection (DLI) as described for example in US 2009/0 226 612A1 . In this method the transition metal-containing compound or the organic acid is typically dissolved in a solvent and sprayed in a carrier gas or vacuum. If the vapor pressure of the transition metal-containing compound or the organic acid and the temperature are sufficiently high and the pressure is sufficiently low the transition metal-containing compound or the organic acid is brought into the gaseous state. Various solvents can be used provided that the transition metal-containing compound or the organic acid shows sufficient solubility in that solvent such as at least 1 g/l, preferably at least 10 g/l, more preferably at least 100 g/l. Examples for these solvents are coordinating solvents such as tetrahydrofuran, dioxane, diethoxyethane, pyridine or non-coordinating solvents such as hexane, heptane, benzene, toluene, or xylene. Solvent mixtures are also suitable.

Alternatively, the transition metal-containing compound or the organic acid can be brought into the gaseous state by direct liquid evaporation (DLE) as described for example by J. Yang et al. (Journal of Materials Chemistry C, volume 3 (2015 ), pages 12098-12106). In this method, the transition metal-containing compound or the organic acid is mixed with a solvent, for example a hydrocarbon such as tetradecane, and heated below the boiling point of the solvent. By evaporation of the solvent, the transition metal-containing compound or the organic acid is brought into the gaseous state. This method has the advantage that no particulate contaminants are formed on the surface.

It is preferred to bring the transition metal-containing compound or the organic acid into the gaseous state at decreased pressure. In this way, the process can usually be performed at lower heating temperatures leading to decreased decomposition of the transition metal-containing compound or the organic acid. It is also possible to use increased pressure to push the transition metal-containing compound or the organic acid in the gaseous state towards the solid substrate. Often, an inert gas, such as nitrogen or argon, is used as carrier gas for this purpose. Preferably, the pressure is 10 bar to 10⁻⁷ mbar, more preferably 1 bar to 10⁻³ mbar, in particular 1 to 0.01 mbar, such as 0.1 mbar.

The exposure of the substrate with the transition metal-containing compound or the organic acid can take from milliseconds to several minutes, preferably from 0.1 second to 1 minute, in particular from 1 to 10 seconds. The longer the substrate at a temperature below the decomposition temperature of the transition metal-containing compound or the organic acid is exposed to the transition metal-containing compound or the organic acid the more regular films are formed with fewer defects.

Preferably, the temperature of the substrate is 5 °C to 40 °C higher than the place where the transition metal-containing compound or the organic acid is brought into the gaseous state, for example 20 °C. The temperature of the substrate needs to be below the decomposition temperature of the organic-inorganic hybrid film, usually it is in the range of 100 °C to 300 °C, such as 160 °C to 260 °C.

By repeatedly bringing the substrate in contact with a transition metal-containing compound and an organic acid in the gaseous state an organic-inorganic hybrid film is formed. The organic-inorganic hybrid film contains a transition metal and an organic acid or its salt. Ideally, it contains alternating layers of transition metal and the organic acid or its salt, wherein the organic acid may bind or coordinate to the transition metal. However, in practices, the organic-inorganic hybrid film can also contain remainders of the ligands contained in the transition metal-containing compound and other imperfections. The organic-inorganic hybrid film can contain 10 to 90 wt.-% transition, for example 30 to 70 wt.-%, depending on the transition metal and the organic acid. The organic-inorganic hybrid film can contain 10 to 90 wt.-% organic acid, for example 20 to 60 wt.-%, depending on the transition metal and the organic acid.

The process according to the present invention further comprises decomposing the organic-inorganic hybrid film into a transition metal-containing film by thermal treatment. A thermal treatment may mean heating the organic-inorganic hybrid film to a temperature above its decomposition temperature. The temperature of the thermal treatment can be 250 °C to 1000 °C, preferably 300 °C to 800 °C, for example 350 °C to 500 °C. Usually, the temperature of the thermal treatment is higher than the temperature during formation of the organic-inorganic hybrid film, preferably it is at least 20 °C higher than the temperature during formation of the organic-inorganic hybrid film, more preferably at least 50 °C, in particular at least 100 °C. The thermal treatment can be in an inert atmosphere, for example in vacuum, nitrogen or argon, or in an oxidizing atmosphere, for example in air, oxygen, ozone, or in a reducing atmosphere, for example in hydrogen, hydrazine or carbon monoxide. Alternatively or additionally, it is possible that the thermal treatment includes exposing the substrate to irradiation, for example to UV irradiation, or to a plasma, for example an oxygen plasma. The thermal treatment can take various amounts of time depending on the transition metal-containing film to be obtained, often 1 s to 1 h, for example 1 min to 30 min.

The process according to the present invention yields a transition metal-containing film. A film can be only one monolayer of a metal or be thicker such as 0.1 nm to 1 μm, preferably 0.5 to 50 nm. A film can contain defects like holes. These defects, however, generally constitute less than half of the surface area covered by the film. The film preferably has a very uniform film thickness which means that the film thickness at different places on the substrate varies very little, usually less than 10%, preferably less than 5%. Furthermore, the film is preferably a conformal film on the surface of the substrate. Suitable methods to determine the film thickness and uniformity are XPS or ellipsometry.

The film obtained by the process according to the present invention can be used in an electronic element. Electronic elements can have structural features of various sizes, for example from 1 nm to 100 μm, for example 10 nm, 14 nm or 22 nm. The process for forming the films for the electronic elements is particularly well suited for very fine structures. Therefore, electronic elements with sizes below 1 μm are preferred. Examples for electronic elements are field-effect transistors (FET), charge-trap memory cells, solar cells, light emitting diodes, sensors, or capacitors. In optical devices such as light emitting diodes or light sensors the film obtained by the process according to the present invention serves to increase the refractive index of the layer which reflects light.

Preferred electronic elements are transistors. Preferably the film acts as chemical barrier metal in a transistor. A chemical barrier metal is a material which reduces diffusion of adjacent layers while maintaining electrical connectivity.

### EXAMPLES

### Example 1

In an ALD reactor (Plasma Electronic GmbH) a Si wafer coupon with a native SiOx layer was heated to 220 °C. It was brought in contact to Ni(dmap)₂ (dmap=dimethylamino-2-propoxide) vapor, purged with argon, then brought in contact to oxalic acid vapor followed by a purge with argon. This sequence was performed 300 times. An organic-inorganic hybrid film was obtained with a thickness of 158 nm as determined by ellipsometry. This organic-inorganic hybrid film was subject to thermal treatment by heating to 400 °C under an argon flow for 1 hour. A film with a metallic appearance was obtained which contained 49 at.-% Ni as determined by X-ray photoemission spectroscopy (XPS) element profiling.

### Example 2

The procedure of example 1 was repeated, wherein Ni(iPrAMD)₂ (iPrAMD=N,N′-diisopropyla-cetamidinate) was used as transition metal-containing compound and deposition was carried out at 240 °C and the sequence was performed 600 times. The growth rate, monitored in-situ by a quartz crystal microbalance, was 8.4 Hz/cycle. An organic-inorganic hybrid film was obtained with a thickness of 99 nm as determined by ellipsometry. A film with a metallic appearance was obtained which contained 45 at.-% Ni as determined by X-ray photoemission spectroscopy (XPS) element profiling.

### Example 3

The deposition procedure described in example 2 was repeated, wherein formic acid was used instead of oxalic acid. The reactor temperature was set to 160, 200 and 240 °C successively and 100 ALD cycles were performed at each temperature. The growth rate, monitored in situ by a quartz crystal microbalance, was 1.8 Hz/cycle or lower at all temperatures.

### Example 4

The procedure of example 2 was repeated, wherein Ni(EtCp)2 (EtCp=Ethylcyclopentadienyl) was used as transition metal-containing compound. The growth rate, monitored in-situ by a quartz crystal microbalance, was 8.8 Hz/cycle. An organic-inorganic hybrid film was obtained with a thickness of 69 nm as determined by ellipsometry. A film with a metallic appearance was obtained which contained 39 at.-% Ni as determined by X-ray photoemission spectroscopy (XPS) element profiling.

### Example 5

The deposition procedure described in example 4 was repeated, wherein formic acid was used instead of oxalic acid. The reactor temperature was set to 140, 180, 220 and 260 °C successively and 100-200 ALD cycles were performed at each temperature. The growth rate, monitored in-situ by a quartz crystal microbalance, was 0.2 Hz/cycle or lower at all temperatures.

### Example 6

The procedure of example 1 was repeated, wherein Ni(Cp)₂ (Cp=Cyclopentadienyl) was used as transition metal-containing compound and deposition was carried out at 220 °C and the sequence was performed 1000 times. An organic-inorganic hybrid film was obtained with a thickness of 140 nm as determined by ellipsometry. This organic-inorganic hybrid film was subject to thermal treatment by heating to 300 °C under a hydrogen flow for 1 hour. A film with a metallic appearance was obtained which contained 75 at.-% Ni as determined by X-ray photoemission spectroscopy (XPS) element profiling.

1-11. (canceled)

12. A process for preparing a transition metal-containing film on a substrate comprising:
(a) forming an organic-inorganic hybrid film by repeatedly bringing the substrate in contact with a transition metal-containing compound and an organic acid in the gaseous state, wherein the organic acid is oxalic acid, glyoxylic acid, or glycolic acid, and
(b) decomposing the organic-inorganic hybrid film into a transition metal-containing film by thermal treatment.

13. The process according to claim 12, wherein the transition metal is Cr, Mn, Fe, Co, Ni, Cu, Nb, Mo, Ru, Rh, Pd, Ag, W, Re, Os, Ir, Pt, or Au.

14. The process according to claim 12, wherein the transition metal is nickel or ruthenium.

15. The process according to claim 12, wherein the transition metal-containing film is a transition metal film.

16. The process according to claim 12, wherein the transition metal-containing film has a thickness of 0.5 to 50 nm.

17. The process according to claim 12, wherein the transition metal-containing compound is a transition metal cyclopentadienyl complex.

18. The process according to claim 12, wherein the organic acid is oxalic acid.

19. The process according to claim 12, the organic-inorganic hybrid film is formed at a temperature of 160 C to 280 C.

20. The process according to claim 12, wherein forming the organic-inorganic hybrid film is performed as atomic layer deposition process containing multiple times a sequence containing bringing the substrate in contact with a transition metal-containing compound, removing residual transition metal-containing compound from the gas phase, bringing the substrate in contact with an organic acid and removing residual organic acid from the gas phase.

21. The process according to claim 12, wherein thermal treatment is performed by heating the organic-inorganic hybrid film in an inert atmosphere to a temperature of 350 C to 450 C.

22. The process according to claim 12, wherein the organic-inorganic hybrid film contains 20 to 60 wt.-% organic acid.
